(19) United States
(12) Patent Application Publication
(10) Pub. No.: US 2021/0134571 A1
(43) Pub. Date: May 6, 2021

(54) IMPROVEMENTS IN AND RELATING TO COATING PROCESSES

(71) Applicants: GENCOA LTD, Liverpool, Merseyside (GB); NANO4ENERGY SLNE, Madrid (ES)

(72) Inventors: Victor BELLIDO-GONZALEZ, Liverpool, Merseyside (GB); Iván FERNÁNDEZ, Madrid (ES); Ambiörn WENNBERG, Madrid (ES); Dermot Partick MONAGHAN, Liverpool, Merseyside (GB)

(21) Appl. No.: 16/640,795

(22) PCT Filed: Aug. 21, 2018
(86) PCT No.: PCT/GB2018/052369

§ 371 Date: Feb. 21, 2020

(30) Foreign Application Priority Data
Aug. 21, 2017 (GB) 1713385.1

(51) Int. Cl. H01J 37/34; C23C 14/35; H01J 37/32

(52) U.S. Cl. CPC H01J 37/3408; H01J 37/3467; H01J 37/32669; C23C 14/355

(57) ABSTRACT

An apparatus (1b) and method of depleting a plasma of electrons in a plasma coating apparatus is disclosed. The invention involves generating a plasma comprising ions (9), particulate material (5) and electrons (6) adjacent a target (4); forming a plasma trap (52) to constrain the plasma near to the target (4), and depleting the plasma of electrons by: providing an additional magnetic field (8b) that is superimposed over the magnetic field of the plasma trap (3, 52), which extends beyond a boundary layer (52) of the plasma trap, and which draws electrons (6) from, or near to, the boundary layer (52) of the plasma trap away from the target (4). The invention proposes applying a baseline voltage (50) to the target (4); and by applying periodic voltage pulses (13b) to the target (4). The additional magnetic field (8b) depletes the plasma of electrons, such that when a voltage pulse (13b) is applied to the target (4), ions (9) can be ejected from the plasma with reduced electron shielding. This has been shown to improve ion bombardment and reduce adverse electron bombardment effects.

This invention relates to improvements in and relating to coating processes, and in particular, but without limitation, to improvements in and relating to plasma coating processes.

Many modern manufacturing processes involve applying surface coatings to objects. Surface coatings can be applied in many ways, but this disclosure is principally concerned with coatings applied using a plasma.

A typical plasma coating process uses a target, which is made from a material that the user wishes to deposit/coat onto a substrate (the object to be coated). A plasma, that is to say, an ionised gas comprised of ions and free electrons, is generated in the vicinity of the target. In addition, an arrangement of permanent or electromagnets is used to create a magnetic field adjacent to, or surrounding, the target (a “plasma trap”), which causes the plasma to be confined adjacent the target.

Ions within the plasma collide with the surface of the target, and if the collision energy is sufficient, this can cause material from the latter to be ejected from the target's surface, whereupon it enters, and forms part of, the plasma.

Then, if an electric field is applied, for example by biasing the substrate, some of the ejected material from the target can be attracted or pushed towards the substrate. If conditions are favourable, at least some of the ejected material from the target attaches to the substrate, thereby forming a coating on it.

The thickness of the coating can be controlled by controlling the “exposure time” of the substrate to the flux of depositing material, as well as the rate at which material is ejected from the target and transported to the substrate. The quality, that is to say, the density, uniformity, adhesion, smoothness, etc. of the resultant coating is also affected by the materials in question, as well as the plasma and deposition parameters.

It will be appreciated by the skilled reader that there are a great many variables in plasma coating systems, such as the configuration of the magnets and their resultant fields, the electric field parameters, as well as the geometry of the apparatus and the physical relationship between the target, substrate and other elements within the system. In addition, the plasma can be controlled by varying the vacuum level within the system, as well as by controlling the composition and partial pressure of the various process gases.

In a plasma coating arrangement, there are generally two principal interactions with the substrate (the object to the coated), namely, the interaction between the relatively heavy ions within the plasma and the substrate; and the interaction between the relatively light electrons within the plasma and the substrate. Each has different effects on the coating quality.

Specifically, ionisation in vacuum plasma deposition systems normally occurs due to collisions between electrons and atoms and/or molecules. In most of these types of system, controlling the electrons can be used to guide positive ions and this is due to weak electric fields generated by the movement of the electrons. In other words, a “cloud” of moving (negative) electrons can draw (positive) ions along with them, ideally towards the substrate. The use of an electric field, therefore, to attract the electrons towards the substrate can be used to displace positive ions towards the substrate also. Coating growth responds to both electron bombardment and ion bombardment (the interaction between the electrons and ions with the substrate, respectively).

Ion bombardment is often needed to obtain dense coatings or films, whereas electron bombardment sometimes brings undesired effects, such as anodic effects which can often cause the deposited film/coating to heat-up. Excessive heating of the film/coating during deposition (and subsequently) can adversely affect its properties and/or quality, as will be well-understood by the skilled reader.

For example, in the case of a very thin metal film deposited onto a polymer substrate: if the electron bombardment is high and a high current is established to ground, the heat generated on the deposited film (due, for example, to anodic discharge) could damage the substrate. Hence, there are a number of process where separation of, and/or being able to independently control, the electron and ion bombardments would bring beneficial effects.

In the case of magnetron sputtering, by way of example, the use of unbalanced magnetrons can cause ion bombardment at the same time as electron bombardment. This has the effect of creating a dense coating/film, but at the expense of heat at the substrate, which can form a highly-stressed coating/film. If, however, electron bombardment could be eliminated, the ion bombardment would also disappear, and the coating growth would not be dense, but rather columnar. Hence, the separation of electrons from ions is of interest in order to allow ion bombardment and dense films without substrate damage and with reduced stress.

Bipolar Pulsed DC magnetron sputtering is known to produce high-energy ions, for example, as described by Bradley et al., in “The distribution of ion energies at the substrate in an asymmetric bi-polar pulsed dc magnetron discharge” [Plasma Sources Sci. Technol. 11 (2002) 165-174]. However, when the electron “cloud” travels with the ions, there is a limitation of the interaction with substrate. For example, carbon (C) deposited without electron filtering will typically produce coatings with around one-third of the hardness achieved when the electrons are being filtered, which is part of the present invention. In order to increase hardness under conditions known in the prior art, the usual method would be to apply a strong negative bias to the substrate. However, this can prove impossible when the substrates cannot be biased, such as where the substrates are dielectric, semiconductors, or made from electrically-insulative materials, such as glass, ceramics and plastics. This can also be difficult to achieve where the substrates can be biased, but where the increase in hardness comes at the expense of increased stress, which can cause film failure due to delamination.

In some other cases like C sputtering or diamond-like carbon (DLC) deposition (for example via Plasma Assisted Chemical Vapor Deposition (PACVD)), the electron bombardment typically induces low hardness, or even plasma polymerisation. Hence, in these cases also, the separation of, or independent control of, ion and electron bombardment would benefit the deposition of hard carbon coatings with low stress.

It will be appreciated from the foregoing that a solution is needed to one or more of the above problems, and/or that a means of separating and/or independently controlling, ion and electron bombardment would be beneficial. This invention aims to provide such a solution and/or an alternative to known plasma deposition techniques.

Aspects of the invention are set forth in the appended independent claim or claims. Preferred and/or optional features of the invention are set forth in the appended dependent claims.

Accordingly, the present invention relates to the generation and control of positive ions and substrate bombardment control while also controlling the electron bombardment on the substrate. The device and method of the present invention is suitably able to produce hard, dense thin films using strong ion bombardment and low electron bombardment. The deposition according to the method of the present invention may achieve low-stress films and/or low damage on substrates.

According to one aspect of the invention, there is provided a plasma coating apparatus comprising: a target; means for generating a plasma adjacent the target, the plasma comprising ions, particulate material and electrons; and an electron depletion device.

In a plasma coating apparatus according to the invention, the means for generating a plasma adjacent the target will typically comprise an electric power source, which biases the target, and a magnetic arrangement. The magnetic arrangement is typically configured to form a “plasma trap”, that is to say, a region of relatively high magnetic field strength, which confines the plasma to a region adjacent the target. Plasma traps, and magnetic arrangements for creating them, will be well-known to, and understood by, the skilled reader and do not require further elaboration here.

The plasma thus created will inevitably contain a mixture of free electrons, ions (e.g. ionised gas molecules) and target material in proportions determined by the process parameters. Incidentally, the target material is present in the plasma due to the interaction of the plasma with the target's surface.

The object of most, if not all, plasma coating systems is to deposit the target material (which is now in the plasma) onto a substrate. The ions and electrons can be used to assist the deposition of the target material onto the substrate, for example, by ion and electron bombardment, as previously mentioned.

In many cases, the substrate will be biased relative to the target, and this causes the ions at the outer edges of the plasma trap, which can escape the plasma trap due to the rapid drop-off in magnetic field strength near to the plasma trap's boundary, to be attracted towards the substrate. The moving ions can often entrain target material, thus transporting it towards the substrate, as well as providing ion bombardment effects as well.

One problem with biasing the substrate is that it can attract or repel ions and/or electrons, depending on their respective polarities. Biasing the substrate is therefore, preferably, avoided if possible. As mentioned previously, some substrates cannot be biased, or are best not biased.

Particularly where the ions are positively charged, they will tend to be quite strongly associated with a “cloud” of free electrons, which are naturally attracted to the positive ions. The problem with this is that a positive ion surrounded by free electrons can effectively be net-neutral, thus making it difficult to control using electric fields. If, on the other hand, the plasma can be depleted of electrons, then fewer free electrons will be present to associate with the ions, thereby reducing the aforesaid “shielding effect”.

According to the invention, there is provided an electron depletion device, which provides this function. Suitably, the electron depletion device is configured to deplete, in use, the plasma of electrons. This has the effect of reducing the electron shielding of the ions to a biased substrate by the electrons surrounding them, or to other electric fields.

The electron depletion device of the invention suitably comprises two main parts, namely: a magnetic part; and an electric part.

The magnetic part suitably comprises one or more magnets, which could be electromagnets, or permanent magnets. The power and/or polarity of the electromagnets is suitably adjustable. Alternatively, where permanent magnets are used, their position(s) and orientation(s) are suitably adjustable. The magnetic part is suitably configured to create a magnetic field, which is superimposed over the magnetic field of the plasma trap.

As will already be readily apparent to the skilled reader, the “range” of the plasma trap is relatively short and well-defined—effectively having a “boundary layer” where the magnetic field strength drops-off very suddenly. On the other hand, the magnetic part of the electron depletion device is designed to have a relatively long-range effect, that is to say, extending from the target significantly beyond the boundary of the magnetic field trap.

It is somewhat trite physics to state that electrons follow magnetic fields and that ions follow electric fields, but in this case, these two facts are important to properly understanding how the invention works.

When a plasma has been set up, ions, target material and electrons will be confined close to the target by the magnetic field trap. However, ions, target material and electrons close to the boundary of the magnetic field trap will see a rapid-drop off in their confinement as they reach, or cross, the magnetic field trap boundary—and this is where the magnetic part of the electron depletion device comes into play:

Electrons that are able to escape the (relatively short-range) magnetic field trap are guided by the (relatively long-range) magnetic field created by the magnetic part of the electron depletion device. The “escaped” electrons are thus guided by the magnetic field created by the magnetic part of the electron depletion device—away from the plasma trap. Preferably, an electron sink is provided, towards which the escaped electrons are guided. The electron sink can be a positively-biased element, which attracts and effectively consumes the escaped free electrons.

By this process, over time, and as more and more electrons are removed from the boundary of the plasma trap, so the “concentration” of electrons in the plasma overall reduces—in other words, the plasma becomes depleted of electrons.

Once the plasma has become electron-depleted, this is where the electric part of the electron depletion device comes into play:

The electric part of the electron depletion device essentially comprises an electric power supply and controller that enables the target to be biased positively or negatively. In certain practical applications, the electric part is formed as part of the primary power supply for biasing the target to create the plasma, but a separate and/or dedicated power supply could equally or alternatively be used for this purpose.

In the case where positive ions are used for ion bombardment, the electric part negatively biases the target so as to attract and retain the positive ions within the plasma trap region. When the electron depletion of the plasma is sufficient (i.e. the plasma is sufficiently depleted of electrons to reduce or remove the electron shielding effect mentioned above), the electric part of the electron depletion device is momentarily reversed. In this example, a short positive voltage pulse is applied to the target, and this repels the positive ions with sufficient impetus for them to escape the plasma trap and thus bombard the substrate.

In the alternative case—where negative ions are used in the ion bombardment, the target is positively biased by the electric part—to attract and/or retain the negative ions within the plasma trap region. Again, when the electron depletion of the plasma is sufficient (i.e. the plasma is sufficiently depleted of electrons to reduce or remove the electron shielding effect mentioned above), the electric part of the electron depletion device is momentarily reversed. In this example, a short negative voltage pulse is applied to the target, and this repels the negative ions with sufficient impetus for them to escape the plasma trap and thus bombard the substrate.

In either case, as the ions are ejected from the plasma (by a “push force”), there is then no (or a reduced) need to bias the substrate (in this case negatively) to attract the ions (by a “pull force”) towards the substrate, and this too addresses and/or overcomes one or more of the aforesaid problems associated with substrates that cannot be, or are best not, biased.

Further, and particularly in the case of positive ion bombardment, because the plasma is pre-depleted of electrons at the point where the momentary reversal of the bias to the target occurs, the momentary bias reversal has a much greater effect than might otherwise be the case, and thus imparts a much higher impetus to the ions—due to the lack of electron shielding of the ions, which would otherwise reduce the interaction between the ions and the voltage pulse.

Suitably, the aforesaid pulse or pulses will typically be between 10 ns and 2 ms (or about 10 ns and 2 ms) in duration, and may have a repetition rate (“rep rate”) of between 10 Hz and 500 kHz (or about 10 Hz and 500 kHz).

In addition to the primary separation of electrons from the electric field pulse, a suitable electron filter could be added in order to limit the number of electrons that arrive at the substrate. In this way, a substantial positive bias can be generated on the growing film and substrate during the pulsated change of the electric field of the electrode.

The voltage on a floating bias substrate could be from +0V to +2000V depending on the ion energy and ion density arriving at the substrate. The substrate voltage and current themselves could also be controlled in such a way as a suitable positive bias and/or suitable current and/or electron density and/or positive ion density could be modulated in specific or varied values, specific or varied pulse rises, peaks and decays. This could control the way the growing film receives bombardment, and/or the resulting stress of the growing film.

The electron depletion device is configured to selectively deplete, in use, the plasma of electrons, thus reducing the shielding of the ions and in doing so, the ions can be accelerated towards the substrate in the presence of a strong electric field. In doing so, upon impact on the substrate, a substrate bias can be achieved.

The electron depletion device is suitably configured to deflect the magnetic field in such a way that the electrons, which by nature would be trying to follow the accelerated positive ions, would be inhibited or prevented from doing so—as they are being deflected by the electric part of the electron depletion device.

The electron depletion device effectively operates as an electron filter, which serves, in use, to avoid or reduce ion deceleration, such that the moving/travelling ions are able to impact the substrate without significant energy loss.

In certain embodiments, the electric part of the electron depletion device is suitably adapted to apply short-duration pulses of electric field, which pulses are long enough to attract the relatively light and mobile electrons from the plasma, but which pulses are insufficiently long and/or powerful as to markedly affect the trajectory of the relatively larger and/or heavier and/or less-mobile ions within the plasma. By this mechanism, the plasma can be depleted of electrons, for example by attracting the electrons to another region outside the plasma zone, thus facilitating the attraction of the ions in the plasma towards a substrate.

The essence of this invention, therefore, is a system which uses a pulsed electric field applied to a plasma (e.g. via the target) to deplete the plasma of electrons. In a deposition system, such as in a magnetron sputtering device, this can enhance the speed and/or trajectory and/or energy of ions and particulate matter within the plasma towards a substrate to be coated, resulting in much harder and/or more continuous and/or smoother deposited layer.

According to another possible aspect of the invention, there is provided a device and method for the generation and control of positive ions and substrate bombardment control is described. The positive ions are generated in a plasma nearby region of an electrode via suitable ionising collisions of atoms and/or molecules with energetic electrons. In order to separate electrons and ions a pulsated change of the electric field is used.

A suitable device or combination of devices enabling the ion generation, pulsated change of the electric field in the plasma region, ion extraction, electron filtering and substrate bias voltage and substrate current management would also be part of the present invention.

The device and method of this invention would mainly relate, although not exclusively, to magnetron sputtering deposition. In addition the ion generation device could be integrated as part of the coating source device or it could also be decoupled from it, as for example in the cases of a thermal evaporation source, a sublimation source, electron beam evaporation, chemical vapour deposition (CVD), Metal organic Chemical Vapour Deposition (MOCVD), inorganic complex vapours, monomer injection, hydrocarbon injection, reactive ion etching, plasma assisted chemical vapour deposition (PACVD) sources or any other vacuum deposition source or technique. The ion generation device could also be independent or could also be part of a magnetron sputtering cathode. The deposition process could be either substantially a non-reactive process (like in physical vapour deposition, PVD), or a reactive process (like in reactive PVD or CVD or PACVD).

The substrate voltage and current management could also form part of the present invention.

Also, the invention may relate to reactive process and coating deposition ion bombardment management. This invention may also relate to the use of present device in feedback control systems; where the feedback could be based on the coating process parameters, or the ion generation parameters or the substrate ion bombardment, voltage or current parameters or any combination of the process parameters.

Feedback control of non-reactive and reactive processes are also part of the present invention.

The ion generator could also have a variety of surface profiles in order to shape the direction of the electric field change and consequently the direction of the ion bombardment, in this way direction control of the ions could be achieved.

This invention also relates to the use of the device with planar, profiled targets or rotatable targets in magnetron sputtering or in any other vacuum deposition process.

In another part of the present invention, this invention also relates to the use of one or a plurality of these devices.

The present invention also relates to the use of different power modes such as single DC Pulsed power, Dual DC Pulsed power, Super-imposed pulse on AC-MF power, HIPIMS, dual HIPIMS, anodic pulse discharges and any combination of power modes which can be added or subtracted to the discharge.

The present invention also relates to the use of an anode which could be by magnetic or non-magnetic means guide the electrons in such a way that an electrons separation from the ions is also achieved. Electric field control of the anode would also allow control of the ion and electron bombardment on the substrate. The anode could be used on planar, profiled and rotatable electrodes.

This invention also relates to materials, components and devices manufactured by methods which use ion-enhanced deposition.

This invention may also relate to generation and control of positive ion emissions from an electrode. The positive ions could be generated in a plasma nearby a region of the electrode via suitable ionising collisions of atoms and/or molecules with energetic electrons. The plasma process could be composed of the ionisation generation period followed by a pulsated change of the electric field which would propel the ions, extracting them towards a substrate where a film is being deposited. A suitable electron filter could limit the number of electrons that would arrive at the substrate in such a way that a substantial positive bias is generated on the growing film and substrate during the pulsated change of the electric field of the electrode. The substrate voltage and current themselves could also be controlled in such a way as a suitable positive bias and/or suitable current and/or electron density and/or positive ion density could be modulated in specific or varied values, specific or varied pulse rises, peaks and decays. This could control the way the growing film receives bombardment and the resulting stress of the growing film.

A suitable device or combination of devices enabling the ion generation, pulsated change of the electric field in the plasma region, ion extraction, electron filtering and substrate bias voltage and substrate current management would also be part of the present invention.

Manufacturing process and methods which use these devices and materials and components processed by the present invention are also part of the invention.

The invention shall now be described, by way of example only, with reference to the accompanying drawings, in which:

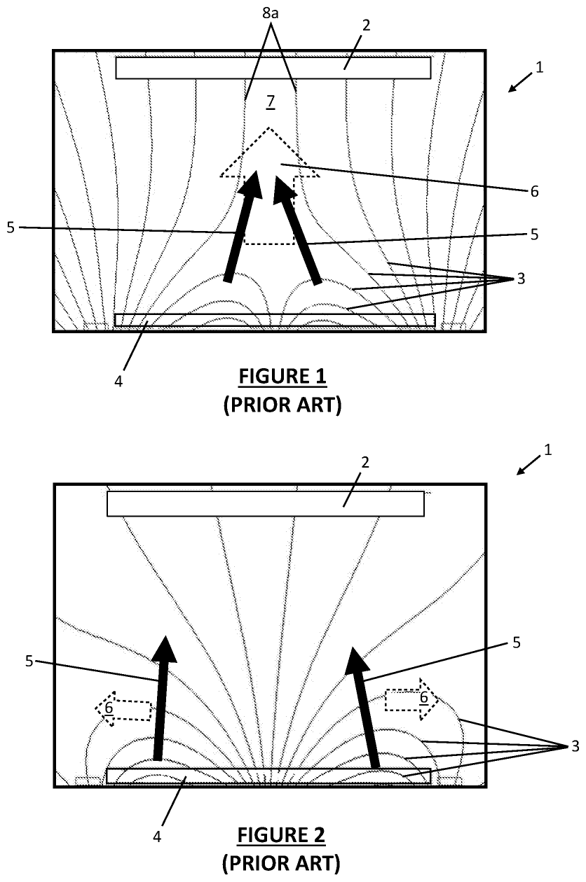

FIG. 1 is a schematic representation of a known magnetron sputtering device in an unbalanced mode of operation;

FIG. 2 is a schematic representation of a known magnetron sputtering device in a balanced mode of operation;

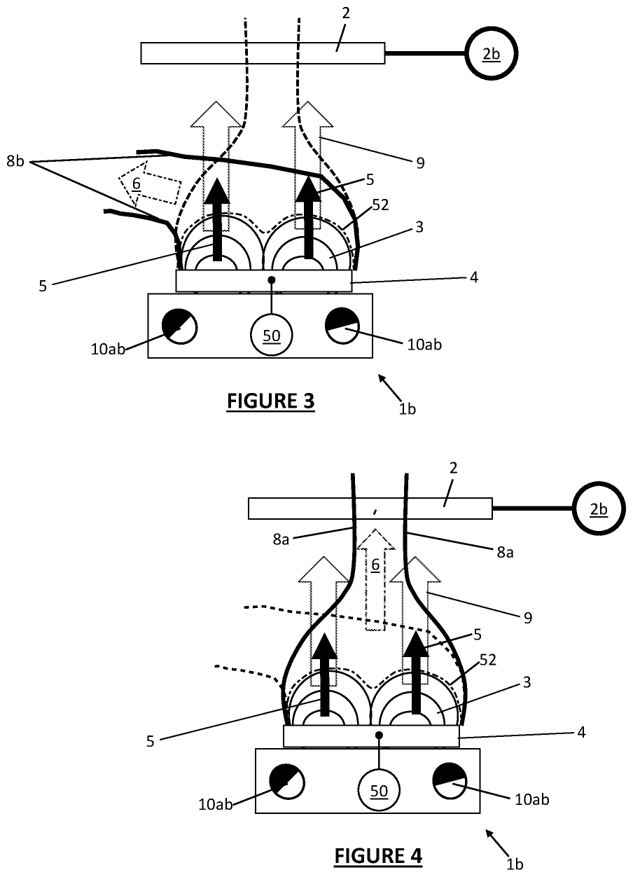

FIGS. 3 and 4 are schematic representations of a first embodiment of the invention in different phases of operation;

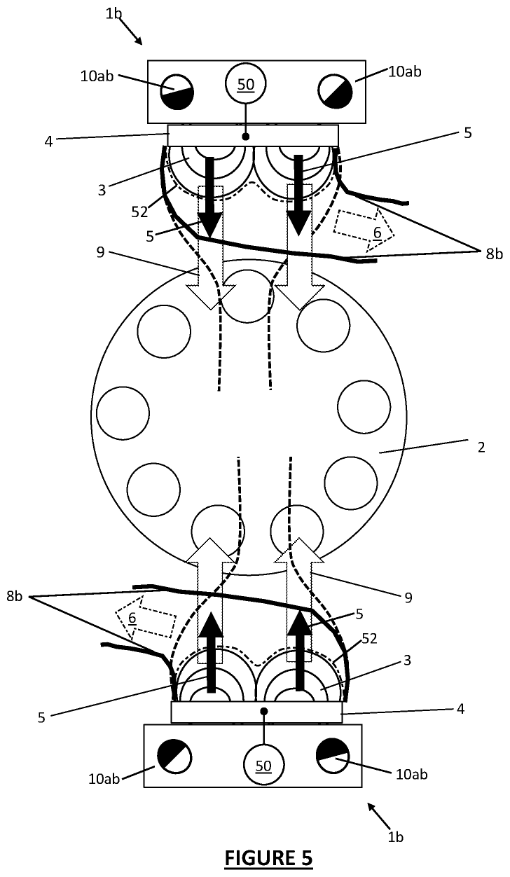

FIG. 5 is a schematic representation of a second embodiment of the invention, comprising two devices as shown in FIGS. 3 and 4, with a rotating substrate stage;

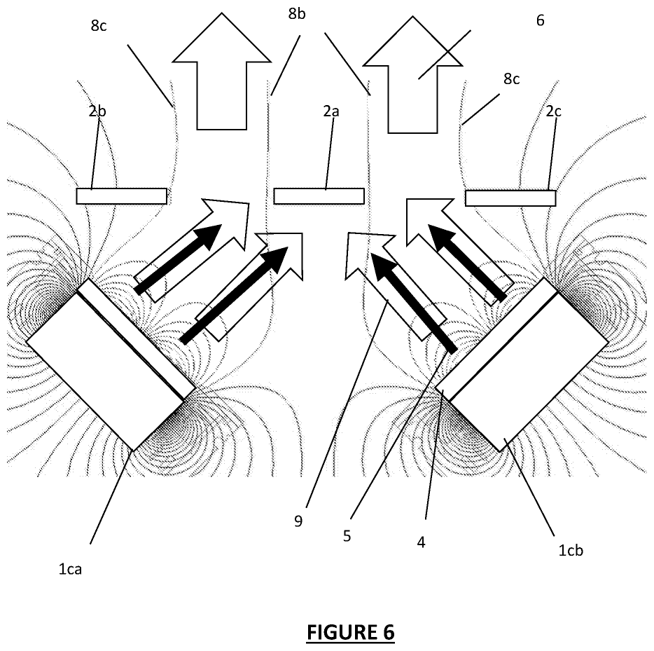

FIG. 6 is a schematic representation of a fourth embodiment of the invention, fitted with an electron filter;

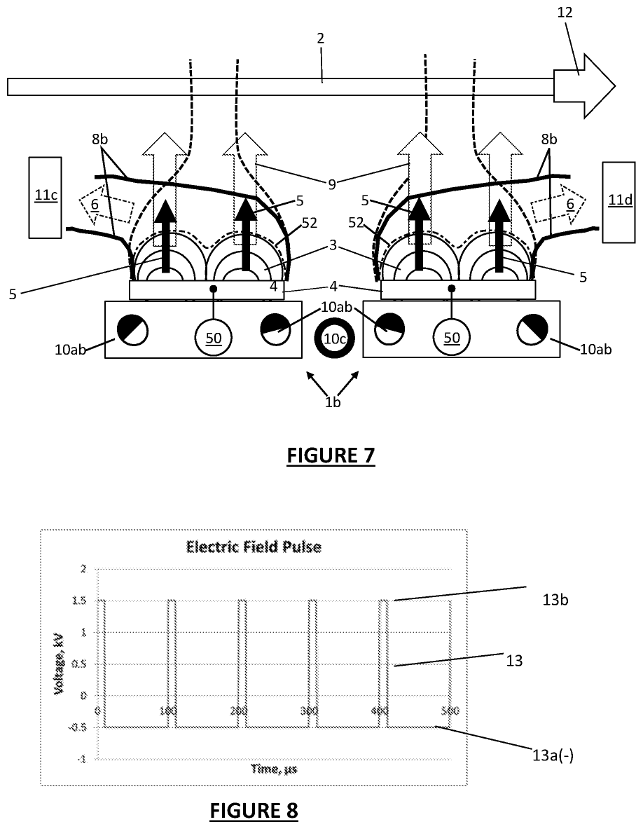

FIG. 7 is a schematic representation of a fifth embodiment of the invention, comprising two opposing devices as shown in FIGS. 3 and 4;

FIGS. 8, 9, 10, 12 and 16 are voltage-time graphs for an electric part of an electron depletion device in accordance with embodiments of the invention, in different modes of operation;

FIG. 11 is an oscilloscope trace corresponding to FIG. 10;

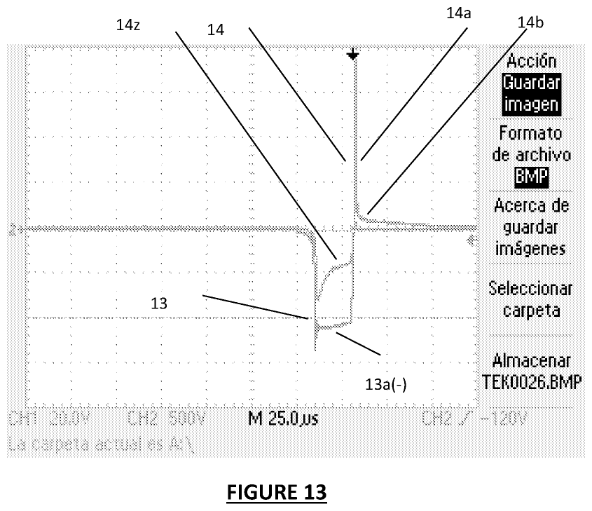

FIGS. 13, 14, 15 and 17 are graphs showing the voltage response at the substrate in response to voltage changes at the target applied by the electric part of an electron depletion device in accordance with the invention;

FIG. 18 is a schematic representation of a sixth embodiment of the invention, comprising a device as shown in FIGS. 3 and 4 in conjunction with an additional evaporation source;

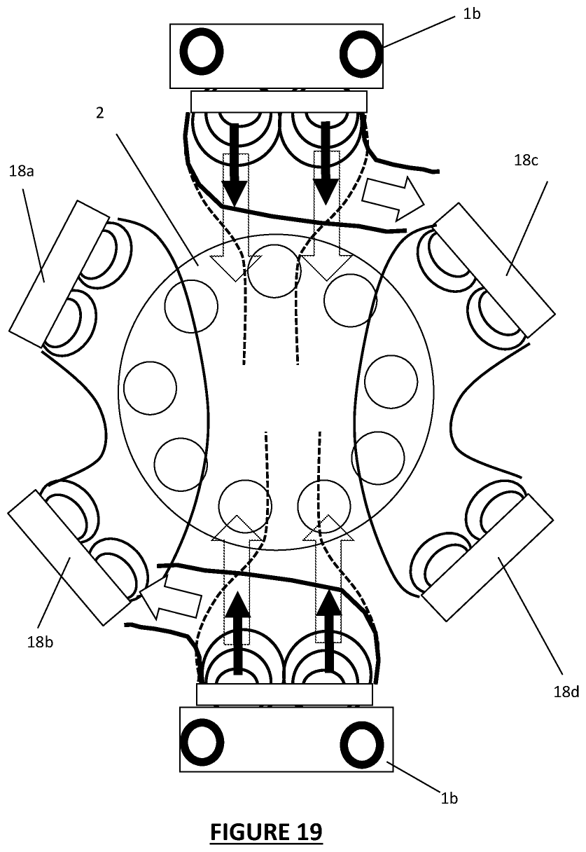

FIG. 19 is a schematic representation of a seventh embodiment of the invention, comprising two opposing devices as shown in FIGS. 3 and 4, a rotating substrate stage and additional magnetic devices;

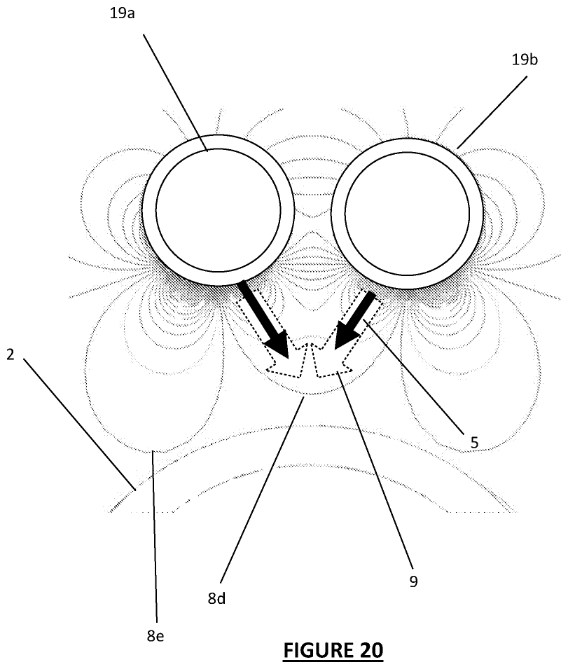

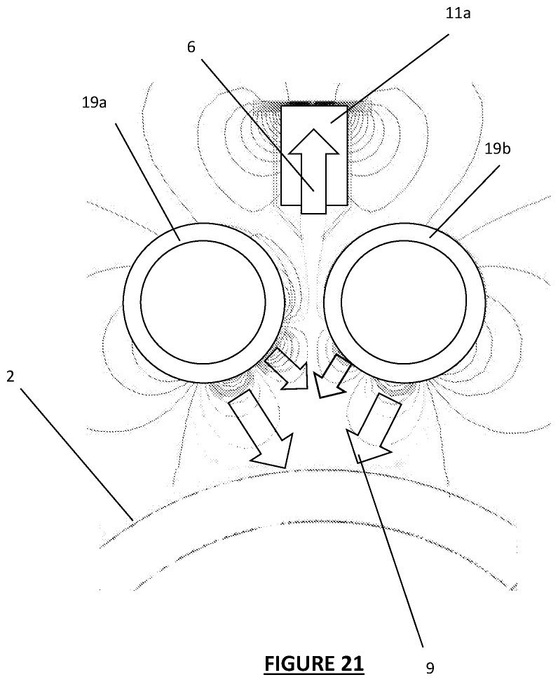

FIGS. 20 and 21 are schematic representations of an eighth and ninth embodiment of the invention, incorporated into a tubular magnetron arrangement;

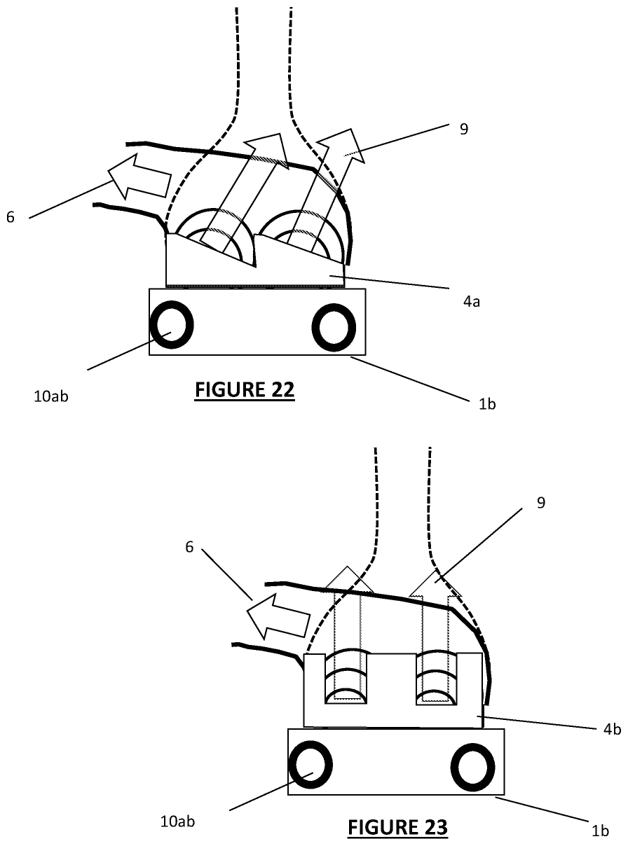

FIGS. 22 and 23 are schematic representations of tenth and eleventh embodiments of the invention, having different target geometries; and

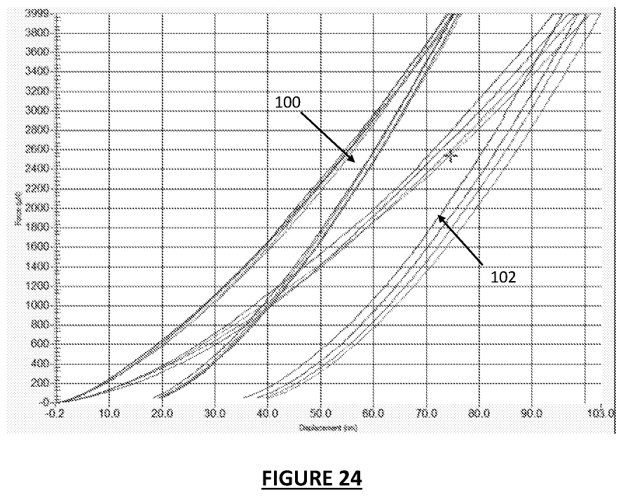

FIG. 24 is a hardness graph (force vs displacement) for coatings formed by the invention versus those formed by known deposition apparatus.

Referring to FIG. 1, a schematic representation of a known magnetron sputtering device 1 is shown. A target 4 is provided, and a magnet arrangement (not shown) is used to create a magnetic field, indicated by magnetic field lines 3 in the drawing, which trap a plasma (not shown for clarity) over the target 4.

The magnetic field is unbalanced, such that an electron flow, indicated generally by dashed arrow 6, bombards a substrate 2 located opposite the target 4. The configuration of the magnetic field is such that electrons are channelled along a path 7 defined by the magnetic field lines indicated 8a in the drawing.

Meanwhile, sputtered material, indicated by solid arrows 5 in the drawing, which is mostly neutral, will preferentially travel in the direction of the electron flow, that is to say, the direction of electron bombardment 6. In unbalanced magnetron configurations, the ion bombardment also brings electron bombardment to the substrate 2. The ions that are part of the plasma will mainly be low energy ions.

Turning now to FIG. 2 of the drawings, the known magnetron sputtering device 1 also has a magnetic field, depicted in the drawing by magnetic field lines 3, which trap plasma (not shown for clarity) over the target 4.

In this case, the magnetic field is balanced, such that the electron flow 6 is now directly outwardly, away from, and so does not reach the substrate 2.

Meanwhile, sputtered material 5, indicated by arrows 5, which is mainly neutral, does not follow the plasma, and so ions that are generated in the plasma will follow the electron flow 6, away from the substrate 2. In balanced magnetrons configurations, the substrate receives minimal ion and electron bombardment.

The difference between a “balanced” and an “unbalanced” magnetron arrangement can be seen by comparing the magnetic field lines 3 shown in FIGS. 1 and 2: those in FIG. 1 radiating generally inwardly towards the substrate 2, with the “lobes” being directed inwardly towards the midline of the arrangement; whereas those in FIG. 2 generally fanning outwardly away from the substrate 2, with the “lobes” being directed outwardly away from the midline of the arrangement.

Turning now to embodiments of the invention, which are shown in the remaining drawings, FIGS. 3 and 4 are schematic representations of a first embodiment of the invention 1b at different stages of operation: in FIG. 3, the device 1b is in a plasma-depletion phase of operation, whereas in FIG. 4, the same device 1b is in an ion bombardment mode of operation.

To avoid unnecessary repetition, identical features are indicated by identical reference signs in the drawings, thus obviating the need for detailed explanation of each embodiment.

In FIGS. 3 and 4 of the drawings, a device 1b, similar to that described previously, contains additional elements namely the magnetic part 10ab, and the electric part 50 of an electron depletion device.

As previously described, the conventional magnetic arrangement (not shown) creates a magnetic field, indicated by magnetic field lines 3, which trap a plasma (not shown) over the target 4. The target 4 is suitably biased according to the present invention, and so sputtering takes place, and sputtered material 5 is ejected from the target 4 and a flux thereof flows towards the substrate 2. By pulsing the electric field, the ions generated in the plasma trap can be impulsed (preferentially ejected from the plasma trap) towards the substrate 2, creating a flux of ions, or an ion flow indicated schematically in the drawings by arrow 9. High energy ions are in this way generated.

In FIG. 3, the electron flow 6 is separate from, or controlled independently of, the ion flow 9. This means that the substrate 2 can be made to receive a mainly positive charge that can be measured on substrate 2. The charge voltage and flow can be managed by suitable power supply means 2b.

The magnetic part 10ab of the electron depletion device comprises a set of permanent magnets, which are arranged adjacent to the magnets (not shown) that form the plasma trap 52 of the magnetron device 1b. The permanent magnets 10ab are generally cylindrical, and are rotated, as indicated schematically in the drawings, so as to form a relatively long-range magnetic field, indicated by schematically by the thick magnetic field lines 8b in the drawings. The relatively long-range magnetic field created by magnets 10ab extends beyond the boundary 52 of the magnetic field trap and so electrons within the plasma, in the vicinity of the magnetic field trap boundary 52, are attracted away from the magnetic field trap boundary 52, as indicated by chain-dash arrow 6. An electron sink (not shown) can be provided downstream of arrow 6 to absorb the attracted free electrons.

Meanwhile, a certain amount of sputtered target material (indicated schematically by solid arrows 5), and ions (indicated by arrows 9), escapes the magnetic field trap boundary 52 in the usual way, and travels towards the substrate 2. It will be appreciated that during this phase of operation, the plasma within, or near to, the magnetic field trap boundary 52 is being depleted of electrons 6, and so the electron concentration of the plasma is constantly reducing; or reaches a suppressed equilibrium concentration. A voltage 2b could be applied to the substrate, but this is not necessary.

In the next phase of operation, as shown in FIG. 4 of the drawings, the electric part 50 of the electron depletion device is activated, by switching from a negative bias state (where it attracted and retained the positive ions) to a positive state for a short duration pulse. As described above, this momentarily repels the positive ions 9, and the electrons 6, away from the target 4 and towards the substrate 2. The impetus is sufficient to overcome the magnetic field 8b produced by the magnetic part 10ab of the electron depletion device, and so at this point in time, the sputtered material 5, the ions 9 and the electrons 6 all move towards the substrate 2. However, as there are now fewer electrons present (due to the depletion in the previous phase of operation), the effect of the positive pulse applied to the target 4 by the electric part 50 of the electron depletion device is much greater, and the electron shielding effect of the electrons 6 on the ions 9 is now greatly reduced. This means that any voltage 2b applied to the substrate 2 has a greater effect, and so the ion bombardment effect is increased, whilst at the same time, the adverse effects of electron bombardment are reduced.

The apparatus 1b is then set back to the electron-depletion mode of operation, and the process repeated.

The electron depletion device enables electron flow to be channelled in different directions, namely: away from the substrate 2 as shown in FIG. 3, in which they are channelled by magnetic field lines 8b; or towards the substrate 2, as in FIG. 4, where they are channelled by magnetic field lines 8a.

As previously mentioned, the magnets 10ab can be electromagnets, which can be switched on/off at will, and/or their power/strength adjusted at will.

In FIG. 4, however, the electron flow 6 and the ion flow 9 both reach the substrate 2. By means of a suitable power supply 2a, the electron and ion current can be managed. Different power modes could be used as described, although not exclusively, as described in greater detail below.

FIG. 5 shows a schematic embodiment of the present invention in which a plurality of the devices 1b are used in order to coat or plasma treat the substrate 2.

Both devices 1b shown in contain magnetic field control elements 10ab able to change the field electron channels between configurations 8a and 8b-c for example. In The configuration 8b-c the electron flow 6 does not reach the substrate 2 while the sputtered material and the ion flow 9 do. Different power modes could be used as described, although not exclusively, as described in greater detail below.

FIG. 6 shows another schematic embodiment of the present invention, where the interaction between devices 1ca and 1cb and their relative position and angle would create magnetic fields 8b-c that would channel the electron flow 6. The material and ion flow 9 (when a suitable electric field pulse is applied) can be different from that of the electrons. The substrate position among the different flows will influence the coating properties. Substrate 2a will mainly receive positive ions. Substrates 2b and 2c will mainly receive coating material. Substrate in position between 2a and 2b or 2c will receive electron bombardment (together with coating material). The ion bombardment will be mainly influenced by low energy ions which follow the electrons. Different power modes could be used as described, although not exclusively, by FIGS. 6, 7 and 10.

FIG. 7 shows another schematic embodiment of the present invention, where two devices 1b are arranged in a relatively parallel position such as those on in-line coating systems coating on substrate 2 which would typically travel in the direction indicated by arrow 12. By magnetic means 10ab or additional magnetic means 10c, the substrate 2 can be shielded from electron flow 6, while the coating flow 5 and high energy ion flow 9 can reach the substrate 2. In addition, anodic elements 11c-d (“electron sinks”) can be added, in conjunction to magnetic shield, in such a way that the electron flow 6 is guided away from the substrate 2 in an enhanced manner. Different power modes could be used as described, as described below.

FIGS. 8, 9 and 10 show examples of three types of electric field pulses, which can be applied using the magnetic part of the electron depletion device.

FIG. 8 represents pulses 13 from a mainly cathodic voltage 13a(−) to the positive value 13b. This would typically belong to the device working in magnetron sputtering mode.

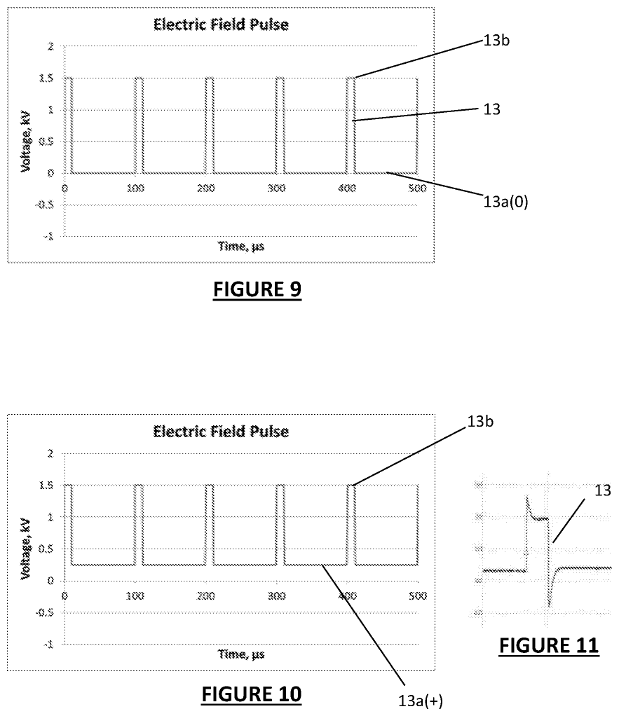

FIG. 9 represents pulses 13 from a grounded or near zero voltage level 13a(0) to a positive level 13b. This would typically belong to the device working mainly in pulsed ion source mode.

FIG. 10 represents pulses from a small positive 13a(+) to a high positive value 13b. A real oscilloscope voltage trace of this latter mode can be seen in FIG. 11 belonging to a pulsed ion source with floating output.

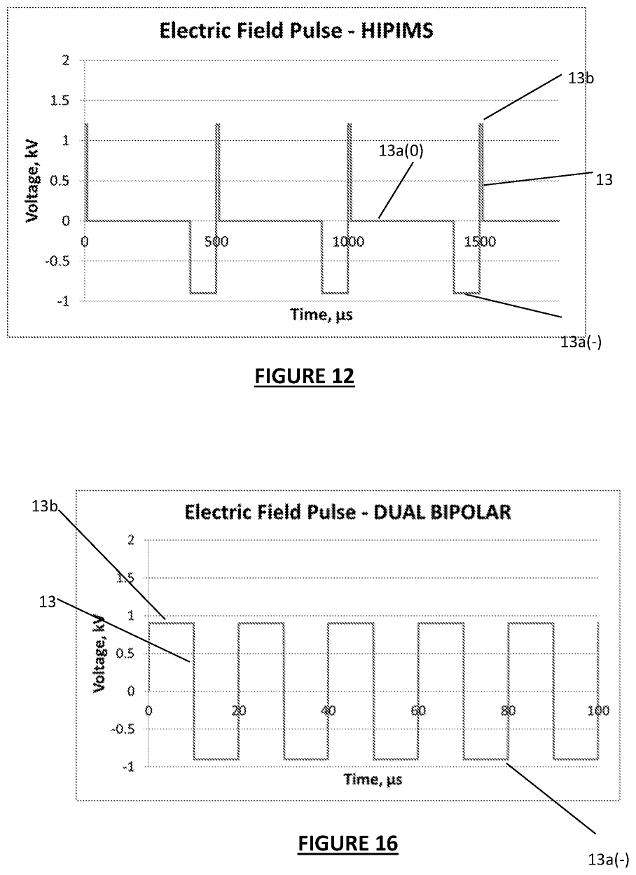

FIG. 12 shows an example of an adaptation of the HIPIMS pulses to the present invention. In FIG. 12 the highly negative pulses 13a(−) are followed by high positive voltage pulse 13b which themselves are followed by a non-energy delivery at 13a(0) voltage.

FIG. 13 shows an example of a HIPIMS discharge of titanium target where traces for the target voltage 13 and substrate floating potential 14 are represented. In a HIPIMS discharge, during the pulse 13a(−) of the target a negative voltage is induced on the target 14z. During the reverse in the electric field a large positive voltage peak 14a is generated on the substrate, with subsequent decay 14b due to charge interactions.

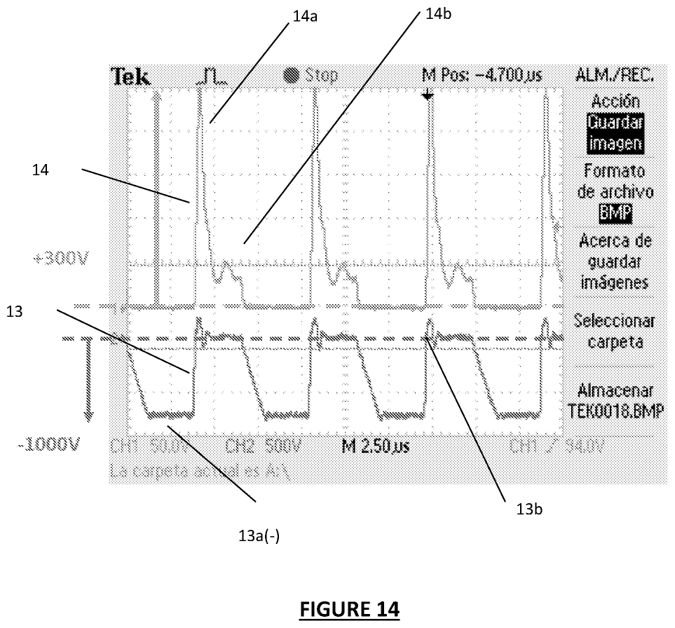

FIG. 14 shows experimental voltage traces 13 of the target and the substrate voltage trace 14. The traces correspond to experimental setup at 150 kHz DC pulsed discharge on the experiment of FIG. 6. With reference to FIG. 6, the substrate position is 2a and the target is 4. The substrate is electrically floating, isolated from ground and electrodes, except through the plasma. In FIG. 14, during the negative cycle 13a(−) on the target positive ions are being formed during the collisions and sputtering process. When reversing the polarity to a positive value, ions are ejected. As the device of FIG. 6 filters the electrons away from the substrate, then a high positive pulse 14a charged of +300V is created on the substrate due to the ion arrival. Natural decays due to interactions will bring the charge value down 14b. By selecting parameters of the discharge, it is possible to alter the values of peak voltage and discharge period.

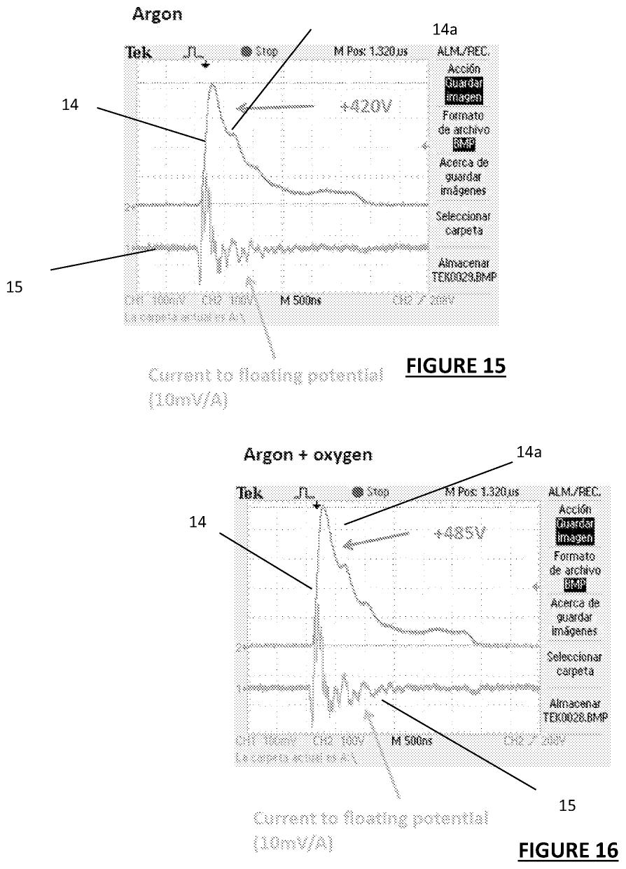

FIG. 15 shows experimental oscilloscope measurements on the substrate of FIG. 6 (substrate 2a) in different gas discharges. FIG. 15 is a plasma discharge in Ar (C-graphite as target material). The trace 14 represents the substrate voltage charge which in the pulse 14a achieves +420 V. The current of the charge 15 on the substrate was also measured.

In FIG. 16, the gas mixture is Ar+O₂. Higher positive ion bombardment is achieved due to the easier ionisation of O₂ with respect to Ar. More positive ions are generated, and more positive ions would arrive at the substrate creating a higher 14a positive pulse. Also, the measured current in trace 15 is higher.

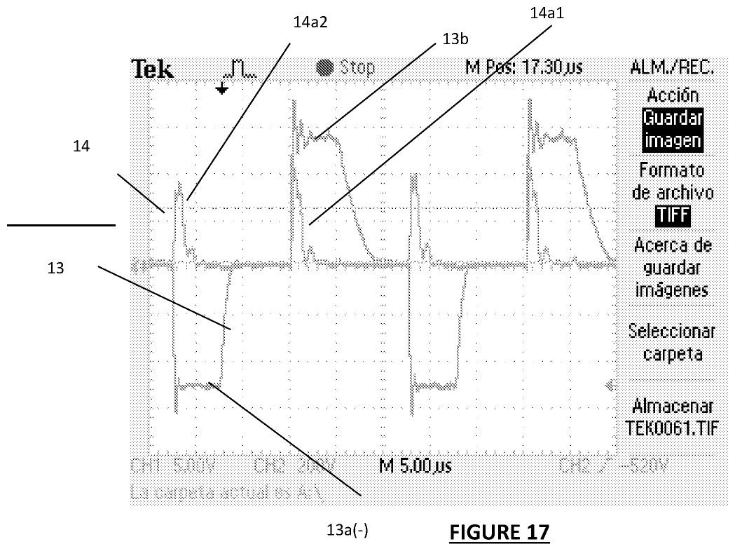

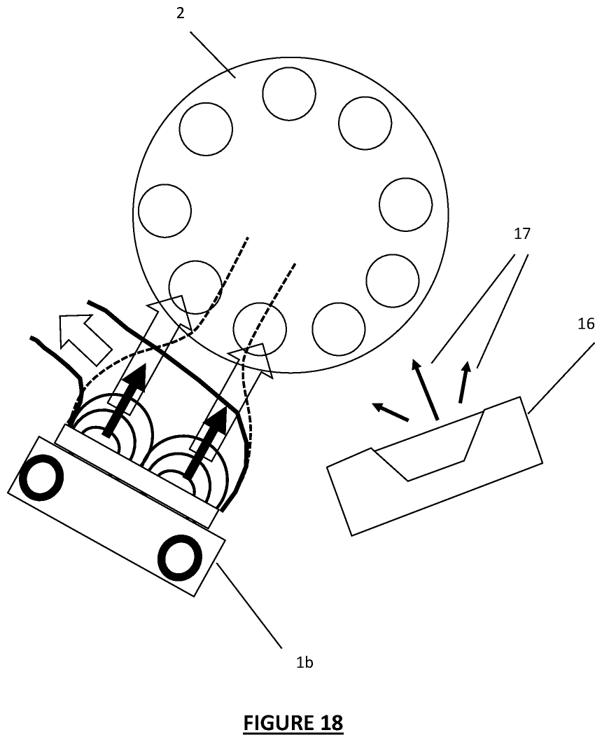

FIG. 16 shows experimental oscilloscope measurements on the substrate of FIG. 6 (substrate 2a) when the cathodes of FIG. 6 are running in dual sputtering mode where the voltage oscillates between the two cathodes as electrodes. FIG. 16 shows a theoretical trace for one of the cathodes of the dual operation mode. The target voltage oscillates between a positive 13b and a negative 13a(−). The substrate charge can be seen in FIG. 17, trace 14. There are two peaks 14a1 and 14a2 which would correspond to the positive impulse on the respective alternating cathodes. For trace 13 of FIG. 17 the period of 13a(−) voltage would generate ions that are emitted during the 13b pulse time. The peak 14a2 corresponds to the ion emission for the other cathode.

FIG. 18 shows another embodiment of the present invention, where the device 1b, described in FIGS. 3 and 4, is used in conjunction with other coating source, such as an evaporation, sublimation or effusion source, 16, which brings coating material 17 over substrate 2. The ion enhancement device 1b is able to bring ion assistance bombardment to the coating material 17, helping to achieve a denser film than those which could be possible by using the source 16 in isolation. Source 16, could be of different nature, from gas or vapour delivery (e.g. monomers, inorganic and organic molecules, MOCVD) source, or a PVD source, such as thermal evaporation, electron beam evaporation, etc. Different power modes could be used as described, although not exclusively, by FIGS. 6, 7 and 10.

FIG. 19 shows another embodiment of the present invention where a plurality of devices 1b as described in FIGS. 3 and 4, are used in conjunction with other coating sources such as magnetron sputtering sources 18a-d. In order to preserve the magnetic electron filter/channel, the overall magnetic interactions need to be considered and adequate control methods need to be implemented. The devices 1b could be used also as coating contributors, both from a target material and a gas material or could also be used as ion enhanced deposition assisting the process of elements 18a-b in their deposition. Different power modes could be used as described, although not exclusively, by FIGS. 8, 9 and 16.

FIG. 20 shows another embodiment of the present invention where the devices of the invention use cylindrical rotatable targets 19a-b with linked magnetic fields in order to create an electron shield via field lines 8d. Ion flux 9 and coating flux 5 arrive to substrate 2. Part of the sputtering zone would need additional shielding, like 8e, which can be achieved by asymmetric magnetic configurations as described in patent U.S. Pat. No. 9,028,660B2. Different power modes could be used as described, although not exclusively, by FIGS. 6, 7 and 10.

FIG. 21 shows another embodiment of the present invention where the devices of the invention use cylindrical rotatable targets 19a-b and the assistance from an anodic element 11a. The anodic element could be enhanced by magnetic means, as described by patent U.S. Pat. No. 9,028,660B2. The electron flow 6 into the anode could be controlled. The electric field in addition to the magnetic confinement of the discharge and electron exchange with the anode would affect the ability of electrons to follow the high energetic ions as they are pulled by the strong electric field towards the active anode. In this way ions 9 will also be able to produce high positive bias on the substrate 2 around the same level as the anodic element 11a. By varying the magnetic interactions on the cathodes, anode and the anodic electric field the system is able to control a variety of ion assistance levels. Different power modes could be used as described, although not exclusively, by FIGS. 8, 9 and 16.

FIGS. 22 and 23 show two schematic representations of the present invention where a different profiled target 4a or 4b could be used on the devices 1b as described in FIGS. 3 and 4. The target profiles 4a and 4b enable the control of the direction of the electric field and consequently the direction of the ion flow 9. Similar to what has been described in FIGS. 3 and 4, the electron flow 6 can be separated from the high energy ion flow 9 by magnetic means 10ab. Additional features such as magnetic or non-magnetic guided anodes can be added and form part of the present invention. Different power modes could be used as described, although not exclusively, by FIGS. 8, 9 and 16.

FIG. 24 is a graph containing data showing the improvement in hardness and elastic modulus of carbon coatings using the current invention compared with prior art systems, with indenter penetration depth plotted on the x-axis, and load plotted on the y-axis. It can be seen that carbon coatings formed using known systems produce hardnessses in the range of 15.1+/−0.7 GPa, and elastic moduli of 167.4+/−4.6 GPa; whereas carbon coatings formed using the invention can produce hardnesses es in the range of 28.4+/−0.6 GPa, and elastic moduli of 237.5+/−2.5 GPa. There is a marked improvement in the hardness and elastic modulus of coatings produced using the invention, as well as reduced variability.

1. A plasma coating apparatus comprising:
a target;
means for generating a plasma adjacent the target, the plasma comprising ions, particulate material and electrons; and
an electron depletion device.

2. The apparatus of claim 1, wherein the means for generating a plasma adjacent the target comprises:
an electric power source, which biases the target, and
a magnetic arrangement, which forms a magnetic field in the vicinity of the target, the magnetic field comprising a plasma trap being a region of relatively high magnetic field strength, which confines a plasma generated by the means for generating a plasma to a region adjacent the target.

3. The apparatus of claim 2, wherein the plasma trap has an outer boundary layer where the relatively high magnetic field strength inside the boundary layer drops-off rapidly as a function of distance from the target.

4. The apparatus of claim 1, wherein the electron depletion device depletes, in use, the plasma of electrons and wherein the electron depletion device comprises a magnetic part and an electric part.

5. (canceled)

6. The apparatus of claim 4, wherein the magnetic part comprises one or more magnets configured to create a magnetic field, which is superimposed over the magnetic field of the plasma trap, the magnetic field created by the magnetic part of the electron depletion device extends beyond the boundary layer of the plasma trap, such that the part of the magnetic field created by the magnetic part of the electron depletion device that extends beyond the boundary layer of the plasma trap draws electrons from, or near to, the boundary layer of the plasma trap away from the target, and the magnetic part further comprises an electron sink.

7. (canceled)

8. (canceled)

9. The apparatus of claim 6, wherein the electron sink comprises a grounded, or positively-biased conductor, which attracts and/or absorbs the electrons drawn from, or near to, the boundary layer of the plasma trap away from the target, the magnet or magnets comprises at least one of 1) electromagnets, whose power and/or polarity is suitably adjustable and 2) permanent magnets, whose position and/or orientation is adjustable.

10. (canceled)

11. (canceled)

12. The apparatus of any of claims 5 to 11 claim 4, wherein the electric part comprises an electrical power supply selectively connectable to the target by a controller, the controller being configured to adjust the power supply so as to apply a specified voltage to the target.

13. The apparatus of claim 12, wherein the controller is configured to at least one of 1) apply a baseline negative voltage to the target, but to apply periodic positive voltage pules to the target, 2) apply a baseline positive voltage to the target, but to apply periodic negative voltage pules to the target, and 3) apply a baseline substantially zero voltage to the target, but to apply periodic positive and/or negative voltage pules to the target.

14. (canceled)

15. (canceled)

16. The apparatus of claim 13, wherein the pulse comprises at least one of 1) duration of the pulses is between about 10 ns and 2 ms, 2) frequency of between about 10 Hz and 500 kHz, 3) magnitude of between about 1 and 1.5 kV relative to the baseline potential.

17. (canceled)

18. (canceled)

19. The apparatus of claim 1, further comprising an electron filter interposed between the plasma and a substrate to be coated.

20. The apparatus of claim 1, further comprising means for retaining a substrate.

21. The apparatus of claim 20, wherein the means for retaining a substrate comprises a voltage measurement device for measuring a voltage at the substrate.

22. The apparatus of claim 21, wherein the controller is configured to adjust any one or more of the magnitude, pulse duration or frequency of the voltage pulses applied to the target in response to a measured voltage at the substrate.

23. The apparatus of claim 22, wherein the controller comprises a feedback circuit adapted, in use, to maintain the voltage measured at the substrate within specified parameters by adjusting any one or more of the magnitude, pulse duration or frequency of the pulses applied to the target.

24. The apparatus of claim 1, further comprising an electrical power supply adapted to at least one of: bias a substrate to be coated and apply a floating bias of between about +0V to +2000V to the substrate.

25. (canceled)

26. (canceled)

27. (canceled)

28. A coating apparatus comprising a plasma coating apparatus of claim 1, further comprising any one or more of: an evaporation source; a target with an inclined surface; a target comprising a cavity.

29. A method of depleting a plasma in a plasma coating apparatus of electrons, the plasma coating apparatus comprising apparatus comprising a target, the method comprising the steps of:
generating a plasma comprising ions, particulate material and electrons adjacent the target using an electric power source, which biases the target, and by using a magnetic arrangement to form a magnetic field in the vicinity of the target, the magnetic field comprising a plasma trap being a region of relatively high magnetic field strength, which confines a plasma generated thereby to a region adjacent the target, the plasma trap having an outer boundary layer where the relatively high magnetic field strength inside the boundary layer drops-off rapidly as a function of distance from the target; and
characterised by depleting the plasma of electrons by:
providing a magnetic field that is superimposed over the magnetic field of the plasma trap and which extends beyond the boundary layer of the plasma trap, which draws electrons from, or near to, the boundary layer of the plasma trap away from the target; and by applying a baseline voltage to the target; and
applying periodic voltage pules to the target.

30. The method of claim 29, wherein the pulse comprises at least one of 1) duration of the pulses is between about 10 ns and 2 ms, 2) frequency of between about 10 Hz and 500 kHz, and 3) magnitude of between about 1 and 1.5 kV relative to the baseline potential.

31. (canceled)

32. (canceled)

33. (canceled)

34. The method of claim 29, further comprising the step of monitoring a voltage at a substrate to be coated, and adjusting any one or more of the duration, frequency or magnitude of the pulses to maintain the voltage at a substrate to be coated within specified parameters.

35. A system comprising:
two or more plasma coating devices, each device comprising:
a target;
means for generating a plasma adjacent the target, the plasma comprising ions, particulate material and electrons; and
an electron depletion device;
wherein at least one pair of the plasma coating devices are at least one of mirrored and opposing.
